(19) United States
(12) Patent Application Publication
(10) Pub. No.: US 2011/0031478 A1
(43) Pub. Date: Feb. 10, 2011

(54) ORGANIC LIGHT EMITTING DIODE DISPLAY DEVICE AND METHOD OF FABRICATING THE SAME

(75) Inventors: Do-Hyun KWON, Yongin-City (KR); Choong-Youl IM, Yongin-City (KR); Dae-Hyun NO, Yongin-City (KR); Jong-Mo YEO, Yongin-City (KR); Ju-Won YOON, Yongin-City (KR); Song-Yi JEON, Yongin-City (KR); Il-Jeong LEE, Yongin-City (KR); Cheol-Ho YU, Yongin-City (KR)

Correspondence Address: ROBERT E. BUSHNELL & LAW FIRM, 2029 K STREET NW, SUITE 600, WASHINGTON, DC, 20006-1004, US

(73) Assignee: Samsung Mobile Display Co., Ltd., Yongin-City (KR)

(21) Appl. No.: 12/712,404

(22) Filed: Feb. 25, 2010

(30) Foreign Application Priority Data
Aug. 7, 2009 (KR) 10-2009-0072861

(51) Int. Cl. H01L 51/52; H01L 51/56

(52) U.S. Cl. 257/40; 438/34; 257/E51.022

(57) ABSTRACT

An organic light emitting diode (OLED) display device and a method of fabricating the same. The OLED display device includes a substrate having a pixel region and a non-pixel region, a buffer layer arranged on the substrate, a semiconductor layer arranged in the non-pixel region of the substrate, a first electrode arranged in the non-pixel region and in the pixel region and electrically connected to the semiconductor layer, a gate insulating layer arranged on an entire surface of the substrate and partially exposing the first electrode in the pixel region, a gate electrode arranged on the gate insulating layer to correspond to the semiconductor layer, a pixel defining layer partially exposing the first electrode, an organic layer arranged on the first electrode; and a second electrode arranged on the entire surface of the substrate.

### CLAIM OF PRIORITY

This application makes reference to, incorporates the same herein, and claims all benefits accruing under 35 U.S.C. §119 from an application earlier filed in the Korean Intellectual Property Office on 7 Aug. 2009 and there duly assigned Serial No. 2009-72861.

### BACKGROUND

1. Field

Non-limiting example embodiments of the present invention relate to an organic light emitting diode (OLED) display device and a method of fabricating the same, in which a first electrode is made out of an interconnection metal, thereby simplifying a process of fabricating a top or bottom light-emitting device.

2. The Related Art

Generally, in OLED display devices, electrons and holes are respectively injected into an emission layer from a cathode (an electron injection electrode) and an anode (a hole injection electrode) and then combined in the emission layer to create excitons, and when the excitons transition from an excited state to a ground state, light is emitted. By such a principle, the OLED display device does not require a separate light source, which is required in a conventional thin film liquid crystal display device, so that its volume and weight can be reduced.

The OLED display device may be classified into a passive-matrix type and an active-matrix type according to its driving mechanism. The passive-matrix OLED display device has a relatively simple configuration, and its fabrication method does not require complicated processes, but the passive-matrix OLED display device has disadvantages in power consumption and size. Also, in the passive-matrix OLED display device, an aperture ratio is reduced as the number of interconnections is increased.

The OLED display device can also be classified into a bottom-emitting structure and a top-emitting structure according to a direction of emitted light generated from an organic emission layer. The bottom emitting structure emits light toward a substrate, and includes a reflective electrode or reflective layer as an upper electrode and a transparent electrode as a lower electrode. Here, when the OLED display device adopts an active-matrix type having a thin film transistor, light does not pass through a portion in which the thin film transistor is formed, resulting in reduction of a light transmissive area. On the other hand, the top-emitting structure has a transparent electrode as an upper electrode, and a reflective electrode or reflective layer as a lower electrode, and thus light is emitted in a direction away from the substrate, resulting in an increased area that the light is emitted, providing increased brightness. Currently, a dual-emission OLED display device that is capable of simultaneously performing top and bottom emitting on one substrate is attracting attention.

However, the conventional OLED display device has no problem when used in the top-emitting type, but is difficult to realize a high quality image due to a decrease in transmittance, caused by an organic layer when used in a bottom-emitting type. In addition, due to a step difference generated when the organic layer in an emissive portion is completely removed, the conventional OLED display device has poor step coverage during deposition of thin films such as a lower electrode, an organic layer and an upper electrode, resulting in failures such as dark spots. Thus, to prevent the failures, technology of improving productivity is required.

### SUMMARY

Non-limiting example embodiments of the present invention provide an organic light emitting diode (OLED) display device, and a method of fabricating the same, in which a pixel electrode is made out of an interconnection metal. More particularly, an OLED display device and a method of fabricating the same, which can reduce the number of mask processes by changing a location of a pixel electrode and increase productivity, are provided.

According to an non-limiting example embodiment of the present invention, there is provided an OLED display device that includes a substrate having a pixel region and a non-pixel region, a buffer layer arranged on the substrate, a semiconductor layer arranged in the non-pixel region of the substrate, a first electrode arranged in the non-pixel region and in the pixel region and electrically connected to the semiconductor layer, a gate insulating layer arranged on an entire surface of the substrate and partially exposing the first electrode in the pixel region, a gate electrode arranged on the gate insulating layer to correspond to the semiconductor layer, a pixel defining layer partially exposing the first electrode, an organic layer arranged on the first electrode and a second electrode arranged on the entire surface of the substrate.

The first electrode can include a source electrode and a drain electrode, both being comprised of a metal. The first electrode can be arranged on source and drain regions of the semiconductor layer. The second electrode can be a transparent conductive layer. The gate electrode does not overlap the first electrode.

According to another non-limiting example embodiment of the present invention, there is provided an OLED display device that includes a substrate having a pixel region and a non-pixel region, a buffer layer arranged on the substrate, a semiconductor layer arranged in the non-pixel region of the substrate, a first electrode arranged in the pixel region and electrically connected to the semiconductor layer, source and drain electrodes arranged on the semiconductor layer in the non-pixel region, a gate insulating layer partially exposing the first electrode in the pixel region and arranged on an entire surface of the substrate, a gate electrode arranged on the gate insulating layer to correspond to the semiconductor layer, a pixel defining layer partially exposing the first electrode, an organic layer arranged on the first electrode and a second electrode arranged on the entire surface of the substrate, wherein the source and drain electrodes can include a substantially same material as the first electrode.

The source and drain electrodes can be a double layer structure. The double layer structure of the source and drain electrodes can include a lower layer extending from the first electrode. The double layer structure of the source and drain electrodes can include a lower layer that includes a substantially same material as the first electrode. The double layer structure of the source and drain electrodes can include a lower layer that includes a transparent conductive material and an upper layer that includes an opaque metal. The first electrode can include a transparent conductive layer. The second electrode can include a reflective conductive layer.

According to another non-limiting example embodiment of the present invention, there is provided a method of making an OLED display device, including providing a substrate having a pixel region and a non-pixel region, forming a buffer layer on an entire surface of the substrate, forming a semiconductor layer on the buffer layer in the non-pixel region, forming a first electrode in the pixel region and in the non-pixel region, the first electrode being connected to the semiconductor layer, forming a gate insulating layer partially exposing the first electrode, forming a gate electrode on the gate insulating layer to correspond to the semiconductor layer, forming a pixel defining layer partially exposing the first electrode, forming an organic layer on the exposed first electrode and forming a second electrode on the entire surface of the substrate.

The first electrode can be patterned to correspond to source and drain regions of the semiconductor layer. The first electrode can be produced by patterning a metal layer for source and drain electrodes. The second electrode can include a transparent conductive material.

According to yet another non-limiting example embodiment of the present invention, there is provided a method of making an OLED display device, including providing a substrate having a pixel region and a non-pixel region, forming a buffer layer on an entire surface of the substrate, forming a semiconductor layer on the buffer layer in the non-pixel region, forming first and second conductive layers connected to the semiconductor layer in the pixel region and in the non-pixel region, forming a gate insulating layer partially exposing the second conductive layer, forming a gate electrode on the gate insulating layer to correspond to the semiconductor layer, forming a pixel defining layer partially a portion of the second conductive layer, forming a first electrode by removing the exposed portion of the second conductive layer, forming an organic layer on the first electrode and forming a second electrode on the entire surface of the substrate.

The method can further include simultaneously patterning the first and second conductive layers that cover an entirety of the semiconductor layer, forming a gate insulating layer on the entire surface of the substrate, forming a pixel defining layer on the substrate, the pixel defining layer exposing a portion of the gate insulating layer in the pixel region, exposing a portion of the second conductive layer in the pixel region by removing the exposed portion of the gate insulating layer and forming a first electrode connected to source and drain electrodes by removing the exposed portion of the second conductive layer in the pixel region.

The source and drain electrodes can have a double layer structure. The double layer structure of the source and drain electrodes can include a lower layer including a first conductive layer and an upper layer including a second conductive layer. The first conductive layer can be a transparent conductive layer and the second conductive layer can be an opaque metal layer. The lower layer of the source and drain electrodes can include a substantially same material as the first electrode. The gate electrode is arranged to correspond to a channel region of the semiconductor layer. The first electrode can include a transparent conductive layer. The second electrode can include a reflective conductive layer.

### BRIEF DESCRIPTION OF THE DRAWINGS

A more complete appreciation of the non-limiting example embodiments of the present invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1A to 1G illustrate an organic light emitting diode (OLED) display device according to a first non-limiting example embodiment of the present invention; and

FIGS. 2A to 2I illustrate an OLED display device according to a second non-limiting example embodiment of the present invention.

### DETAILED DESCRIPTION

Reference will now be made in detail to the present embodiments of the present invention, examples of which are shown in the accompanying drawings, wherein like reference numerals refer to the like elements throughout. The embodiments are described below in order to explain the present invention by referring to the figures.

### First Non-Limiting Example Embodiment

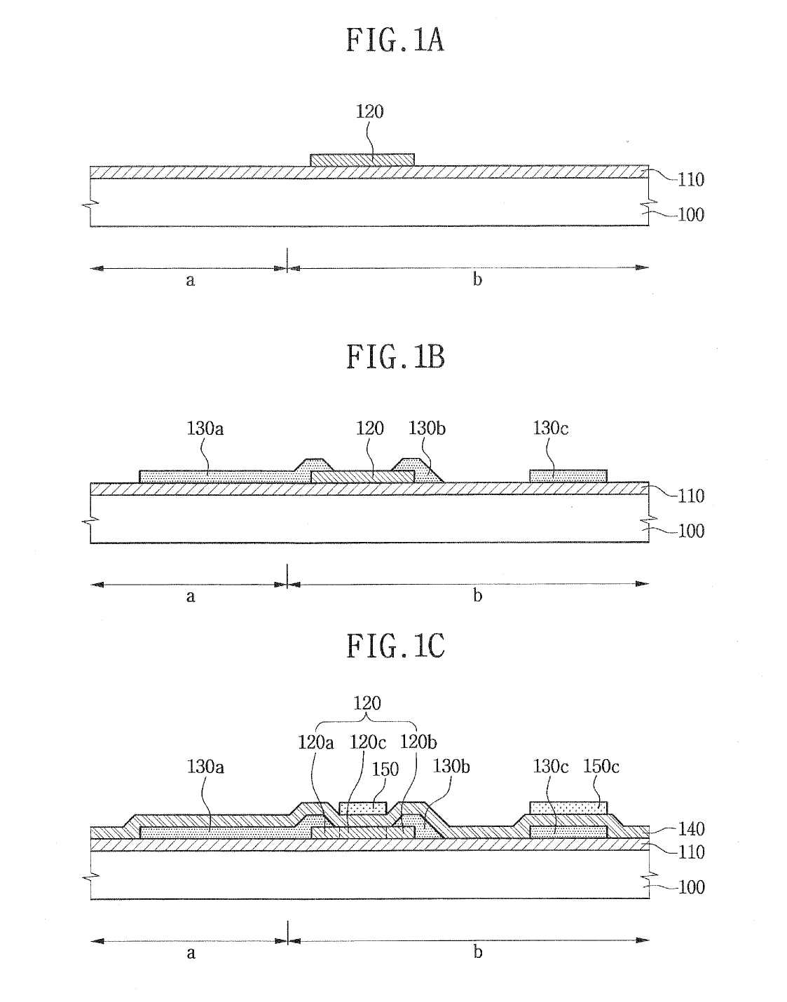

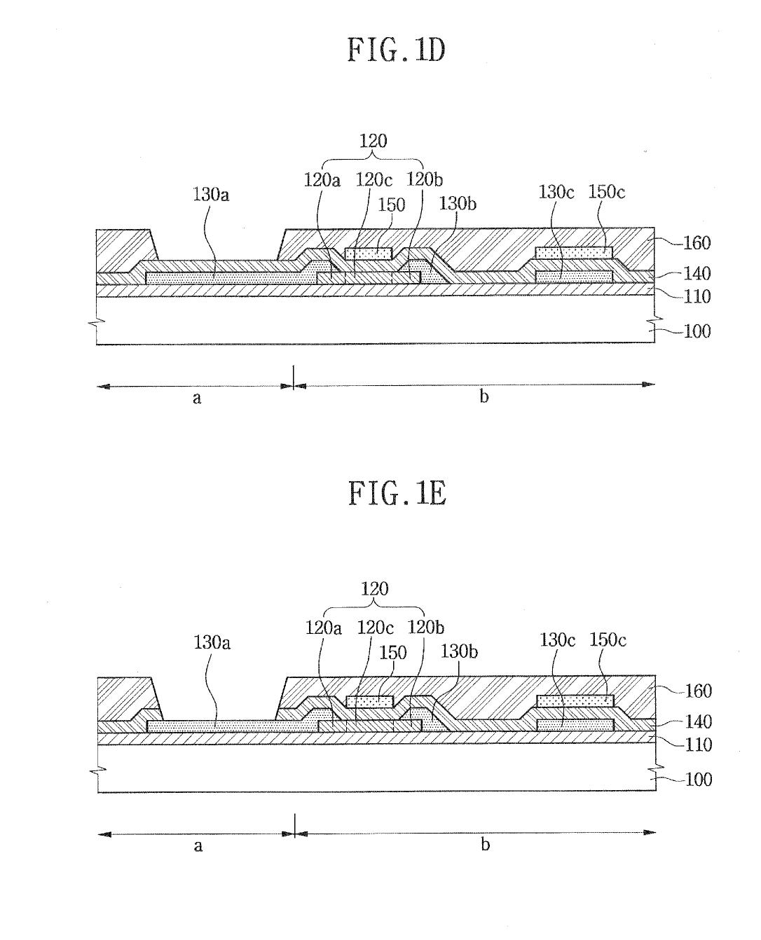

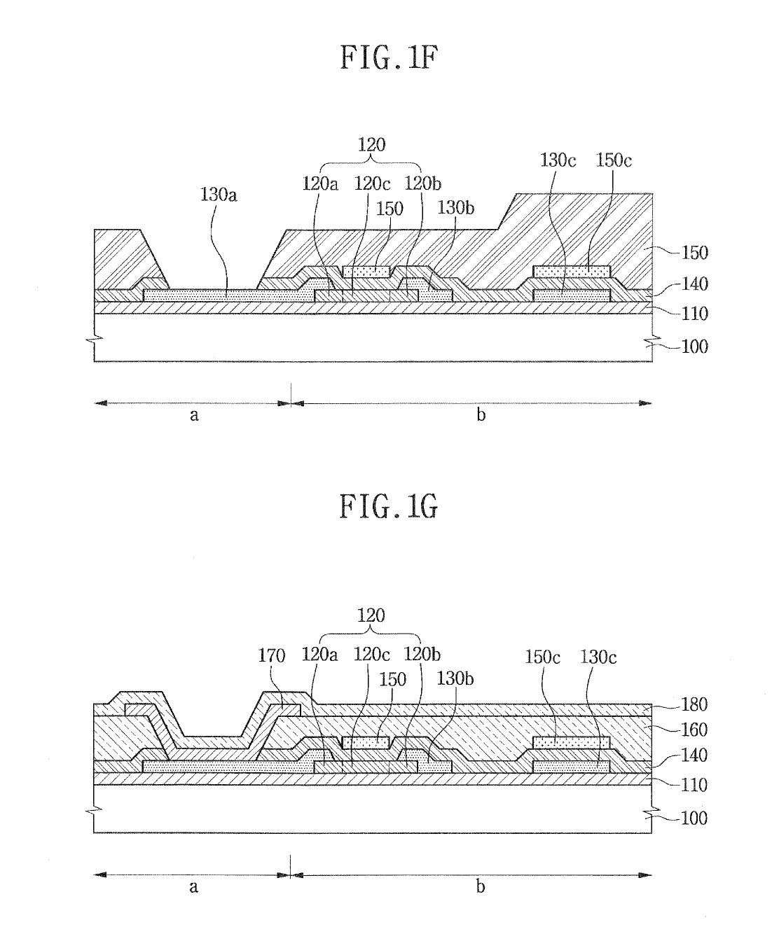

FIGS. 1A to 1G illustrate an organic light emitting diode (OLED) display device according to a first non-limiting example embodiment of the present invention.

Referring to FIG. 1A, a substrate 100 including a pixel region a and a non-pixel region b is provided. Subsequently, a buffer layer 110 is formed on the substrate 100. The substrate 100 is a transparent substrate made out of plastic or glass, and the buffer layer 110 serves to prevent diffusion of moisture or impurities generated by a lower substrate, and can be a single layer or multilayer structure. The layer or layers of the buffer layer 110 can include an oxide layer such as a silicon oxide layer or a nitride layer such as a silicon nitride layer.

A semiconductor layer 120 is formed on the buffer layer 110 in the non-pixel region b. The semiconductor layer 120 is made out of amorphous silicon, which is crystallized into polycrystalline or single crystalline silicon, and then patterned to form the semiconductor layer 120. Here, the amorphous silicon can be deposited by chemical vapor deposition or physical vapor deposition. When or after the amorphous silicon is formed, a process of reducing a concentration of hydrogen by dehydrogenation can be performed. The semiconductor layer 120 can also be formed using an oxide semiconductor layer.

Afterwards, referring to FIG. 1B, first electrodes 130a and 130b are formed to be electrically connected to the semiconductor layer 120. The first electrodes 130a and 130b are patterned to correspond to the pixel region a and the non-pixel region b, and to source and drain regions 120a and 120b respectively of the semiconductor layer 120. Here, the first electrodes 130a and 130b can be made out of a metal to form the source and drain electrodes, and the metal can be one of molybdenum (Mo), chromium (Cr), tungsten (W), molybdenum-tungsten (MoW), aluminum (Al), aluminum-neodymium (Al—Nd), titanium (Ti), titanium nitride (TiN), copper (Cu), a Mo alloy, an Al alloy and a Cu alloy. These may be used alone or in a combination thereof.

During the formation of the first electrodes 130a and 130b, a first electrode interconnection 130c can be simultaneously formed in the non-pixel region b.

Referring to FIG. 1C, a gate insulating layer 140 is fin sued on the entire surface of the substrate 100 having the first electrodes 130a and 130b and the first electrode interconnection 130c. A gate electrode 150 corresponding to the semiconductor layer 120 and a gate interconnection 150c are both formed in the non-pixel region b on the gate insulating layer 140.

The gate electrode 150 is formed to correspond to a channel region 120c of the semiconductor layer 120, but not to correspond to the first electrodes 130a and 130b.

The first electrodes 130a and 130b are connected to and correspond to the source and drain regions 120a and 120b respectively of the semiconductor layer 120, respectively, over the pixel region a and the non-pixel region b and serve as source and drain electrodes.

Here, the gate electrode 150 is produced by forming a metal layer for a gate electrode (not shown) using a single layer of Al or an Al alloy such as Al—Nd or multiple layers in which an Al alloy is stacked on a Cr or Mo alloy, and etching the gate electrode metal layer via photolithography.

Afterwards, referring to FIG. 1D, a pixel defining layer 160 partially exposing the gate insulating layer 140 corresponding to the first electrode 130a, which is disposed in the pixel region a, is formed. The pixel defining layer 160 can be produced by stacking an insulating material, and the insulating material can be an organic or an inorganic material. The organic material can include, but is not limited to, one of photosensitive resins including benzocyclobutenes (BCB), acryl-based photoresist, phenol-based photoresist and polyimide-based photoresist. These may be used alone or in a combination thereof.

Referring to FIG. 1E, the gate insulating layer 140 exposed by the pixel defining layer 160 is removed, thereby partially exposing a portion of the first electrode 130a disposed within the pixel region a.

Referring to FIG. 1F, an organic layer 170 that includes an organic emission layer is formed on the exposed portion of the first electrode 130a, and a second electrode 180 is formed on the entire surface of the substrate 100. Thus, the OLED display device according to the first non-limiting example embodiment of the present invention is completed. The second electrode 180 can be made out of a transparent conductive layer such as indium tin oxide (ITO), indium zinc oxide (IZO), Al₂O₃ (AZO) or Ga₂O₃ doped ZnO (GZO). These may be used alone or in a combination thereof.

The OLED display device according to the first non-limiting example embodiment of the present invention can be fabricated by a simpler process than the conventional five- or six-mask process by using four masks for patterning of the semiconductor layer, the first electrode and the gate electrode, and forming the pixel defining layer.

### Second Non-Limiting Example Embodiment

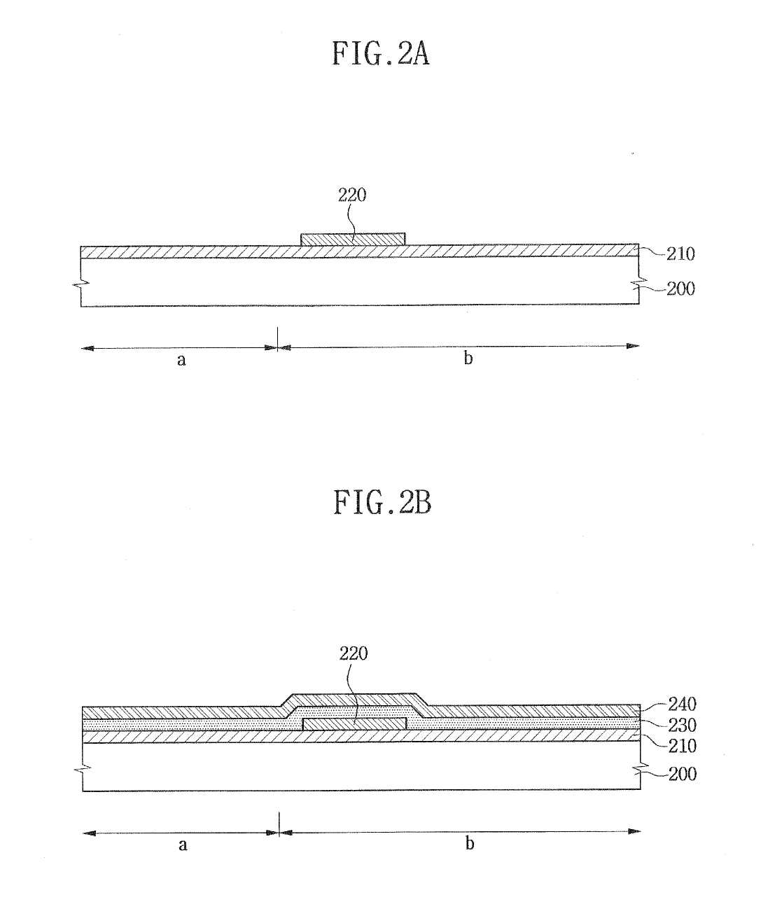

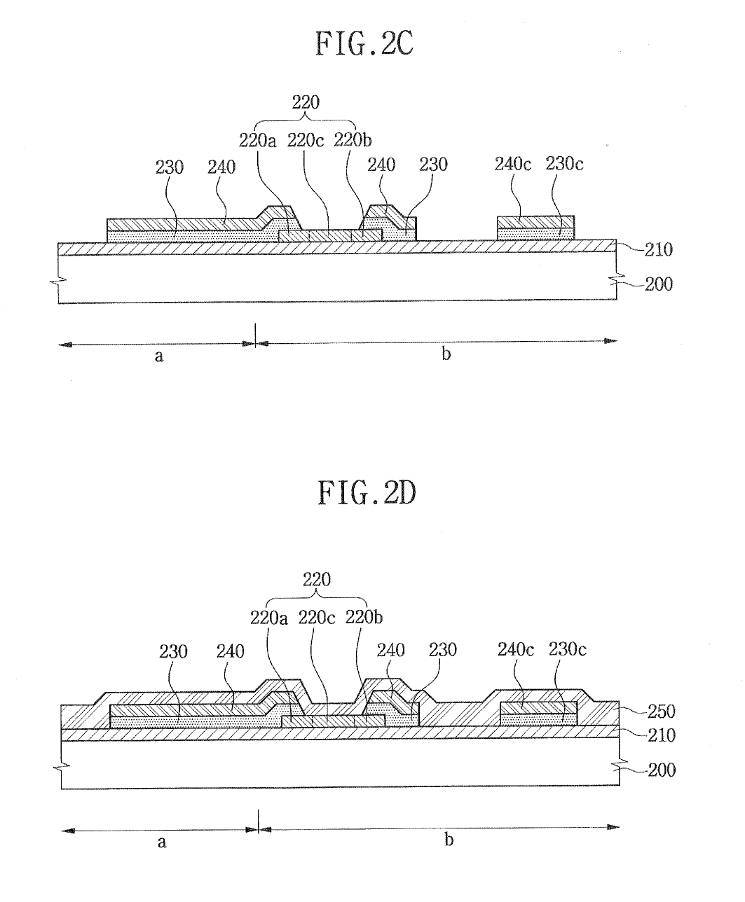

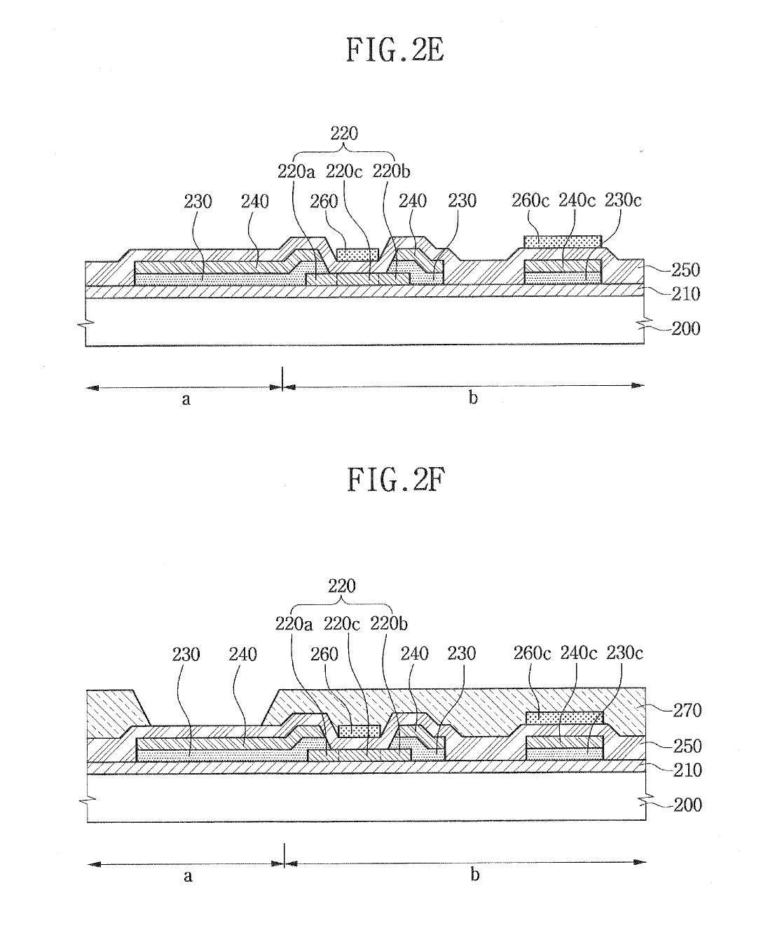

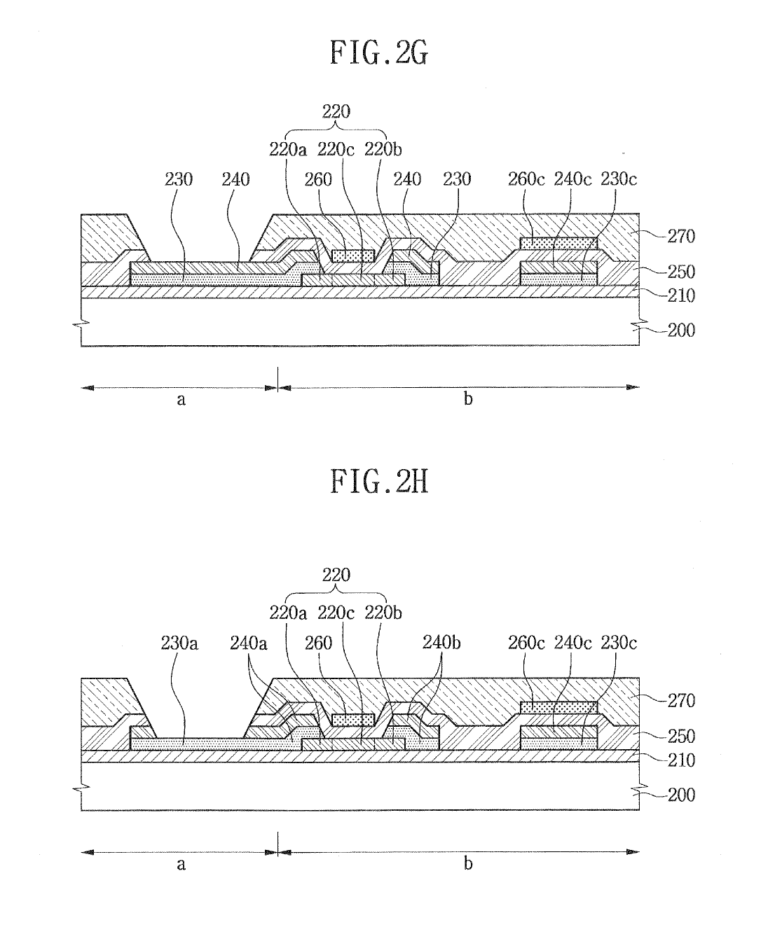

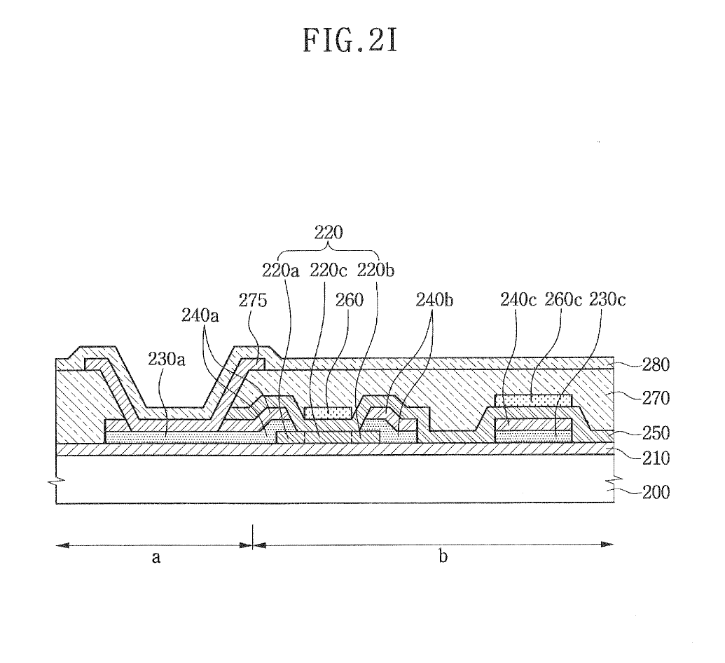

FIGS. 2A to 2I illustrate an OLED display device according to a second non-limiting example embodiment of the present invention.

Referring to FIG. 2A, a substrate 200 including a pixel region a and a non-pixel region b is prepared, a buffer layer 210 is formed on the substrate 200, and a semiconductor layer 220 is formed on the buffer layer 210.

The substrate 200 is a transparent substrate made out of plastic or glass, and the buffer layer 210 serves to prevent diffusion of moisture or impurities generated by lower substrate 200, and is a single layer or multilayer structure where ones of the layers can include silicon oxide or silicon nitride. The semiconductor layer 220 is made out of amorphous silicon, which is crystallized into polycrystalline or single crystalline silicon, and then patterned to form the semiconductor layer 220. Here, the amorphous silicon can be deposited by chemical vapor deposition or physical vapor deposition. During or after when the amorphous silicon is formed, a process of reducing a concentration of hydrogen by dehydrogenation can be performed. The non-limiting example embodiment shows that the semiconductor layer 220 is made out of a silicon layer, but it can also be made out of an oxide semiconductor layer.

Referring to FIG. 2B, a first conductive layer 230 and a second conductive layer 240 are sequentially formed on the entire surface of the substrate 200. The first conductive layer 230 can be a transparent conductive layer, which is a transparent conducting oxide (TCO), for example, ITO or ZnO such as IZO, AZO or GZO, to have a thickness of about 300 to about 500 Å. The second conductive layer 240 can be an opaque and highly conductive metal layer for source and drain electrodes, which can be one of Mo, Cr, W, MoW, Al, Al—Nd, Ti, TiN, Cu, a Mo alloy, an Al alloy, and a Cu alloy. These may be used alone or in a combination thereof.

Afterwards, referring to FIG. 2C, the first conductive layer 230 and the second conductive layer 240 are simultaneously patterned. A first electrode interconnection pattern 230c and an interconnection pattern 240c for the source and drain electrodes can be formed in the non-pixel region b.

Referring to FIG. 2D, a gate insulating layer 250 can be formed on the entire surface of the substrate 200. The gate insulating layer 250 can be a single layer or multilayer structure that can include silicon oxide or silicon nitride.

Referring to FIG. 2E, a gate electrode 260 is formed on the gate insulating layer 250 of the substrate 200 to correspond to the semiconductor layer 220, and a gate electrode interconnection pattern 260c is formed. The gate electrode 260 and the gate electrode pattern 260c can be simultaneously produced.

The gate electrode 260 can be produced by forming a metal layer for a gate electrode (not shown) using a single layer of Al or an Al alloy such as Al—Nd, or multiple layers in which an Al alloy is stacked on a Cr or Mo alloy, and etching the gate electrode metal layer via photolithography.

Referring to FIG. 2F, a pixel defining layer 270 is formed on the entire surface of the substrate 200 except for a portion of the pixel region a. The pixel defining layer 270 can be formed by stacking an insulating material, which can be an organic or inorganic material. The organic material can include, but is not limited to, one of photosensitive resins such as benzocyclobutene (BCBs), acryl-based photoresist, phenol-based photoresist and polyimide-based photoresist. These may be used alone or in a combination thereof.

Referring to FIG. 2G, the portion of the gate insulating layer 250 in the pixel region a exposed by the pixel defining layer 270 is partially removed, thereby partially exposing the second conductive layer 240 in the pixel region a.

Afterwards, referring to FIG. 2H, the second conductive layer 240 exposed by the pixel defining layer 270 is completely etched, thereby exposing the first conductive layer 230 and forming a first electrode 230a and source and drain electrodes 240a and 240b in the pixel region a.

Here, the first electrode 230a is made out of a first conductive layer 230, and the source and drain electrodes 240a and 240b are made out of a second conductive layer 240 and a first conductive layer 230 which are sequentially formed in the source and drain regions 220a and 220b of the semiconductor layer 220.

Referring to FIG. 2I, an organic layer 275, including an organic emission layer, is formed on the exposed portion of the first electrode 230a, and a second electrode 280 is formed on the entire surface of the substrate 200. Thus, the OLED display device according to the second non-limiting example embodiment of the present invention is completed. The second electrode 280 can be made out of a reflective conductive layer, such as Al, Mo, Ag or an alloy thereof. These may be used alone or in a combination thereof.

The OLED display device according to the second non-limiting example embodiment of the present invention can be fabricated by a simpler process than the conventional 5- or 6-mask process by using four masks for patterning the semiconductor layer, the first electrode and the source and drain electrodes, and the gate electrode, and forming the pixel defining layer.

An OLED display device and a method of fabricating the same are provided, in which a first electrode is made out of an interconnection metal, thereby simplifying a process for forming a top or bottom light-emitting device, and increasing production efficiency.

Although the present invention has been described with reference to predetermined non-limiting example embodiments thereof, it will be understood by those skilled in the art that a variety of modifications and variations can be made to the non-example embodiments of the present invention without departing from the spirit or scope of the present invention defined in the appended claims and their equivalents.

What is claimed is:

1. An organic light emitting diode (OLED) display device, comprising:
a substrate having a pixel region and a non-pixel region;
a buffer layer arranged on the substrate;
a semiconductor layer arranged in the non-pixel region of the substrate;
a first electrode arranged in the non-pixel region and in the pixel region and electrically connected to the semiconductor layer;
a gate insulating layer arranged on an entire surface of the substrate and partially exposing the first electrode in the pixel region;
a gate electrode arranged on the gate insulating layer to correspond to the semiconductor layer;
a pixel defining layer partially exposing the first electrode;
an organic layer arranged on the first electrode; and
a second electrode arranged on the entire surface of the substrate.

2. The OLED display device of claim 1, wherein the first electrode comprises a source electrode and a drain electrode, both including a metal.

3. The OLED display device of claim 1, wherein the first electrode is arranged on source and drain regions of the semiconductor layer.

4. The OLED display device of claim 1, wherein the second electrode is a transparent conductive layer.

5. The OLED display device of claim 1, wherein the gate electrode does not overlap the first electrode.

6. An OLED display device, comprising:
a substrate having a pixel region and a non-pixel region;
a buffer layer arranged on the substrate;
a semiconductor layer arranged in the non-pixel region of the substrate;
a first electrode arranged in the pixel region and electrically connected to the semiconductor layer;
source and drain electrodes arranged on the semiconductor layer in the non-pixel region;
a gate insulating layer partially exposing the first electrode in the pixel region and arranged on an entire surface of the substrate;
a gate electrode arranged on the gate insulating layer to correspond to the semiconductor layer;
a pixel defining layer partially exposing the first electrode;
an organic layer arranged on the first electrode; and
a second electrode arranged on the entire surface of the substrate, wherein the source and drain electrodes are comprised of a substantially same material as the first electrode.

7. The OLED display device of claim 6, wherein the source and drain electrodes comprise a double layer structure.

8. The OLED display device of claim 7, wherein the double layer structure of the source and drain electrodes includes a lower layer extending from the first electrode.

9. The OLED display device of claim 7, wherein the double layer structure of the source and drain electrodes includes a lower layer including a substantially same material as the first electrode.

10. The OLED display device of claim 7, wherein the double layer structure of the source and drain electrodes include a lower layer including a transparent conductive material and an upper layer including an opaque metal.

11. The OLED display device of claim 6, wherein the first electrode includes a transparent conductive layer.

12. The OLED display device of claim 6, wherein the second electrode includes a reflective conductive layer.

13. A method of fabricating an OLED display device, comprising:
providing a substrate having a pixel region and a non-pixel region;
forming a buffer layer on an entire surface of the substrate;
forming a semiconductor layer on the buffer layer in the non-pixel region;
forming a first electrode in the pixel region and in the non-pixel region, the first electrode being connected to the semiconductor layer;
forming a gate insulating layer partially exposing the first electrode;
forming a gate electrode on the gate insulating layer to correspond to the semiconductor layer;
forming a pixel defining layer partially exposing the first electrode;
forming an organic layer on the exposed first electrode; and
forming a second electrode on the entire surface of the substrate.

14. The method of claim 13, wherein the first electrode is patterned to correspond to source and drain regions of the semiconductor layer.

15. The method of claim 13, wherein the first electrode is produced by patterning a metal layer for source and drain electrodes.

16. The method of claim 13, wherein the second electrode includes a transparent conductive material.

17. A method of fabricating an OLED display device, comprising:
providing a substrate having a pixel region and a non-pixel region;
forming a buffer layer on an entire surface of the substrate;
forming a semiconductor layer on the buffer layer in the non-pixel region;
forming first and second conductive layers connected to the semiconductor layer in the pixel region and in the non-pixel region;
forming a gate insulating layer partially exposing the second conductive layer;
forming a gate electrode on the gate insulating layer to correspond to the semiconductor layer;
forming a pixel defining layer partially a portion of the second conductive layer;
forming a first electrode by removing the exposed portion of the second conductive layer;
forming an organic layer on the first electrode; and
forming a second electrode on the entire surface of the substrate.

18. The method of claim 17, further comprising:
simultaneously patterning the first and second conductive layers that cover an entirety of the semiconductor layer;
forming a gate insulating layer on the entire surface of the substrate;
forming a pixel defining layer on the substrate, the pixel defining layer exposing a portion of the gate insulating layer in the pixel region;
exposing a portion of the second conductive layer in the pixel region by removing the exposed portion of the gate insulating layer; and
forming a first electrode connected to source and drain electrodes by removing the exposed portion of the second conductive layer in the pixel region.

19. The method of claim 18, wherein the source and drain electrodes have a double layer structure.

20. The method of claim 19, wherein the double layer structure of the source and drain electrodes include a lower layer including a first conductive layer and an upper layer including a second conductive layer.

21. The method of claim 20, wherein the first conductive layer is a transparent conductive layer and the second conductive layer is an opaque metal layer.

22. The method of claim 20, wherein the lower layer of the source and drain electrodes includes a substantially same material as the first electrode.

23. The method of claim 17, wherein the gate electrode is arranged to correspond to a channel region of the semiconductor layer.

24. The method of claim 17, wherein the first electrode includes a transparent conductive layer.

25. The method of claim 17, wherein the second electrode includes a reflective conductive layer.
